(19) United States
(12) Patent Application Publication
(10) Pub. No.: US 2002/0131253 A1
(43) Pub. Date: Sep. 19, 2002

(54) Circuit board and method of manufacturing the same, and display device

(76) Inventor: Yukihisa Kobayashi, Matsumoto-si (JP)

Correspondence Address: HARNESS, DICKEY & PIERCE, P.L.C., P.O. BOX 828, BLOOMFIELD HILLS, MI, 48303, US

(21) Appl. No.: 10/041,935

(22) Filed: Jan. 7, 2002

(30) Foreign Application Priority Data
Jan. 15, 2001 (JP) 2001-006635
Dec. 14, 2001 (JP) 2001-381584

(51) Int. Cl. H05K 7/02; H05K 7/06; H05K 7/08; H05K 7/10

(52) U.S. Cl. 361/760

(57) ABSTRACT

A circuit board 10 including first components 30 which are mounted by solder connection, and a second component 36 which is mounted with an ACF 40 interposed therebetween. The circuit board 10 has a band-shaped region A3 which extends in the shape of a band while including the second component 36, and which does not include any of the first components 30. The band-shaped region A3 is larger in width than the pressing surface of a thermocompression bonding head which is employed in mounting the second component 36.

### BACKGROUND OF THE INVENTION

1. Field to Which the Invention Belongs

The present invention relates to a circuit board and a method of manufacturing the same, and a display device.

2. Description of the Related Art

In general, electronic components are mounted on a circuit board by soldering, and electronic components are mounted thereon by ACFs (Anisotropic Conductive Films). In the circuit board, in order that the components to be mounted by the soldering (hereinbelow, termed “first components”), for example, resistors and capacitors may be efficiently mounted to fabricate the circuit board, a mount technology wherein the circuit board in a state in which the first components are arranged on a solder paste printed is passed through a reflow furnace, thereby to perform solder connection, that is, surface mount technology is usually employed. With the surface mount technology, the whole circuit board becomes a high temperature, for example, 260° C. inside the reflow furnace for melting the solder.

Besides, in recent years, an IC chip etc. have increasingly heightened in the density of integration, and in case of mounting them on a substrate, it has been desired that the mounting be possible with a small occupation area. In this regard, flip chip bonding has come to be often adopted as a mounting method which can comply with the desire. As a bonding system in the flip chip bonding, a system using an ACF is one of major systems. Here, the ACF is ordinarily formed by dispersing a large number of conductive particles-within a resin which has such a property as thermoplasticity, thermosettability or ultraviolet-settability.

Meanwhile, in the mounting which employs the ACF, the IC chip or the like needs to be thermocompression-bonded to the substrate in such a way that the IC chip or the like including bumps, and the substrate including electrodes are opposed with the ACF held therebetween, and that the substrate is pressed while the IC chip or the like is being heated. Often used for the thermocompression bonding is a thermocompression bonding jig including a head which is formed so as to have a width corresponding to that of the IC chip or the like and to be elongate beyond the length of the IC chip or the like. Hereinbelow, the IC chip or the like component which is mounted by employing the ACF shall be termed the “second component”.

The thermocompression bonding jig which has the long head as stated above needs to be used in a state where the first components are not mounted in the surroundings of the IC chip or the like, especially in the surroundings of the IC chip or the like in the lengthwise direction thereof, in order to avoid that the components mounted on the substrate collide against the head to spoil the thermocompression bonding.

Accordingly, a process is considered in which the mounting of the IC chip or the like employing the ACF is performed earlier, whereupon the mounting of the first components based on the surface mount technology is performed. As explained before, however, the whole circuit board needs to be passed through the reflow furnace at the high temperature in the surface mount technology. It has therefore been verified that, when the mounting employing the ACF is followed by the solder reflow treatment as stated above, the ACF is exposed to the high temperature in the solder reflow treatment, so the connection reliability thereof lowers.

The present invention has been made in view of the problem as stated above, and consists in permitting first components to be mounted by the surface mount technology without lowering the reliability of connection by an ACF in case of manufacturing a circuit board.

### SUMMARY OF THE INVENTION

(1) In order to accomplish the object, a circuit board according to the present invention is characterized, in a circuit board having a substrate; a first component which is mounted on the substrate by solder connection; and a second component which is mounted on the substrate through an anisotropic conductive film, by comprising a belt-shaped region which extends in the shape of a belt while including the second component, and which does not include the first component.

According to the circuit board of the above construction, the first component is not mounted on the belt-shaped region which extends in the shape of a belt while including the second component, so that in a case where the second component is mounted by employing a thermocompression bonding jig after the first component has been mounted, the first component is not feared to form an obstacle to make thermocompression bonding unsatisfactory. It is therefore permitted to perform a solder treatment such as solder reflow treatment earlier, and to thereafter perform the mounting with the anisotropic conductive film.

Besides, when it is permitted as stated above to perform the solder treatment earlier and to perform the mounting with the anisotropic conductive film later, a situation where heat in the solder treatment is applied to the anisotropic conductive film does not occur originally, and hence, a situation where connection reliability lowers as regards the anisotropic conductive film is not apprehended to occur.

Owing to the above, in a circuit board which is formed by employing both the mounting with the solder treatment and the mounting with the anisotropic conductive film, the connection reliability can be reliably prevented from lowering as regards the anisotropic conductive film.

(2) Next, in the circuit board of the above construction, the first component can be made a passive element or a mechanism component, and the second component can be made a semiconductor device. Here, a resistor or a capacitor, for example, is considered as the passive element. Also, a variable resistor, for example, is considered as the mechanism component. Besides, an IC chip or an LSI chip, for example, a power source IC or a liquid crystal driving IC is considered as the semiconductor device.

According to the circuit board of this construction, a circuit board can be formed by mounting the passive element or mechanism component in accordance with the solder reflow treatment, namely, the surface mount technology, without lowering the connection reliability of the anisotropic conductive film as contributes to the mounting of the semiconductor device.

(3) Next, in the circuit board of the above construction, the belt-shaped region can be formed wider than a pressing surface of a head of a thermocompression bonding jig which is employed in mounting the second component, that is, a thermocompression bonding head. In this way, even in a case where the thermocompression bonding jig is employed for mounting the second component after the first component has been mounted, the pressing surface or contact surface of the thermocompression bonding head can be used without interfering or colliding with the first component, and hence, appropriate thermocompression bonding can be performed.

(4) Next, in the circuit board of the above construction, an alignment mark can be provided outside the belt-shaped region, for example, outside a side edge part thereof. In this way, it is avoidable that, in mounting the second component such as IC chip, the alignment mark be covered with the anisotropic conductive film.

(5) Next, in the circuit board of the above construction, the solder connection can include a reflow treatment. Here, the “reflow treatment” is a treatment wherein an electronic component is mounted on a substrate on which a solder is put, and it is thereafter soldered to the substrate by heating the solder. In the reflow treatment, the substrate is exposed to a very high temperature. Therefore, when an anisotropic conductive film exists on the substrate during the reflow treatment, it is very likely that the connection reliability of the anisotropic conductive film will lower. However, when the mounting with the anisotropic conductive film is performed after the solder connection or the reflow treatment as permitted to be performed by the circuit board of the present invention, the anisotropic conductive film is not apprehended at all to be exposed to the high temperature during the reflow treatment.

(6) Next, in the circuit board of the above construction, a plurality of such first components can be disposed, and in that case, the belt-shaped region can be located at the intermediate position of the plurality of first components. When the belt-shaped region is arranged between one first component and another first component in this manner, the second component disposed within the belt-shaped region is also arranged between one first component and the other first component. In general, the second component and the plurality of first components are often joined by wiring patterns. In this regard, when the second component is not arranged at a position distant from the plurality of first components, but it is arranged at the intermediate position of the plurality of first components, the wiring patterns between the second component and the plurality of first components can be easily formed.

(7) The circuit board of the above construction in which the belt-shaped region is located between the plurality of first components is especially advantageous in a case where the second component is a power source IC or a power source LSI. The reason therefor is as stated below. Since the power source IC or the power source LSI performs the function of supplying a power source voltage to the large number of first components, a large number of wiring patterns are usually formed between the power source IC or the like and the plurality of first components. Accordingly, when the second component such as the power source IC is arranged at the intermediate position of the plurality of first components, the design of the wiring patterns becomes very easy.

(8) In the circuit board of the above construction, the belt-shaped region can be disposed extending from one end to another end of the substrate. That is, the belt-shaped region can be disposed so as to pass from one end edge to another end edge of the substrate, or it can be disposed extending from the vicinity of one end edge to the vicinity of another end edge.

(9) Besides, in the circuit board of the above construction, the belt-shaped region can be disposed so as to extend rectilinearly. In general, a pressing head for sticking an anisotropic conductive film to a substrate, a compression bonding head for tentatively compression-bonding a second component, and a thermocompression bonding head for formally compression-bonding the second component are often formed to be rectilinear, and hence, the belt-shaped region should desirably be disposed rectilinearly as stated above.

(10) Besides, in the circuit board of the above construction, wiring patterns should desirably be formed in the belt-shaped region. According to the present invention, any of the first components is not included in the belt-shaped region, and hence, a pattern design can be made so that wiring patterns for joining the plurality of first components or for joining the first components and the second component may not be formed in the belt-shaped region. However, the formation of the wiring patterns also within the belt-shaped region is advantageous for making a pattern design by effectively using the area of the substrate.

(11) Besides, in the circuit board of the above construction, a dummy electrode which is substantially equal in area to the second component should desirably be formed on the position of the substrate corresponding to the second component. Here, the “dummy electrode” is a pattern which is formed of the same material as that of electrodes formed on the substrate, but which does not function as an electrode. When such a dummy electrode is disposed on the back side of the second component, the mounted state of the second component can be confirmed in such a way that the deformed state of the dummy electrode is visually confirmed by viewing the mounted portion of the second component from the dummy electrode side, namely, by viewing it from the back side of the substrate. Moreover, when the dummy electrode is joined to a ground potential, noise can be checked from entering the second component.

(12) Next, a display device according to the present invention is characterized by comprising the circuit board of any of the various constructions described above, and display means to which the circuit board is connected.

(13) In the display device of the above construction, the “display means” is an element which displays an image such as characters, numerals or patterns, and it can be constructed of, for example, a liquid crystal display device, an organic EL device, a flat display such as plasma display, or a CRT (Cathode Ray Tube) display. According to the display device of this construction, the circuit board in which the second component is mounted at high reliability is employed, and hence, a display device of high reliability can be obtained.

(14) In the above display device, in a case where the display means is constructed of the liquid crystal device and where a plurality of such first components are disposed on the substrate, the belt-shaped region can be located between the plurality of first components, and the second component can be made a power source IC, a power source LSI, a liquid crystal driving IC or a liquid crystal driving LSI. The power source IC, power source LSI, liquid crystal driving IC or liquid crystal driving LSI is often joined to the plurality of first components by a large number of wiring lines. In such a case, when the power source IC or the like is located at the intermediate position between the plurality of first components, the wiring lines can be easily formed.

(15) Next, a method of manufacturing a circuit board according to the present invention is characterized by comprising the step of mounting a first component on a substrate by solder connection; the step of arranging an anisotropic conductive film on a predetermined position of the substrate; the step of arranging a second component on the anisotropic conductive film; and the step of thermocompression-bonding the second component to said substrate with said anisotropic conductive film held therebetween; wherein said step of arranging said anisotropic conductive film on the predetermined position of said substrate is performed after said step of mounting the first component on said substrate by the solder connection.

According to the circuit board manufacturing method of this construction, the circuit board is manufactured by mounting the second component after the first component has been mounted. It is accordingly avoidable that heat in the solder connection, for example, surface mount technology be applied to the anisotropic conductive film. As a result, the first component can be mounted by the surface mount technology or the like without lowering the reliability of connection based on the anisotropic conductive film.

(16) In the circuit board manufacturing method of the above construction, the step of mounting the first component on the substrate by the solder connection can include a reflow treatment. The reflow treatment is a treatment in which the substrate is exposed to a high temperature. In accordance with the present invention, however, the anisotropic conductive film is not arranged on the substrate yet when the reflow treatment is performed, and hence, it is avoidable that the anisotropic conductive film less immune against the high temperature be exposed to the high temperature during the reflow treatment.

### BRIEF DESCRIPTION OF THE DRAWINGS

FIG. 1 is a plan view showing one embodiment of a circuit board according to the present invention.

FIG. 2 is a plan view showing a substrate for use in the circuit board shown in FIG. 1.

FIG. 3 is a sectional view showing the sectional structure of the substrate shown in FIG. 2.

FIG. 4 is a sectional view showing a state after a solder has been printed at lands on the substrate shown in FIG. 3.

FIG. 5 is a sectional view showing a state after a first component has been mounted on the lands of the substrate shown in FIG. 4.

FIG. 6 is a sectional view showing a state after a second component has been mounted on the substrate shown in FIG. 5, by an ACF.

FIG. 7 is a flow chart showing one embodiment of a manufacturing method for a circuit board according to the present invention.

FIG. 8 is a plan view showing a formal compression bonding step which is one step in the manufacturing method shown in FIG. 7.

FIG. 9 is a sectional view taken along line III-III in FIG. 8.

FIG. 10 is a graph showing a temperature profile in a reflow treatment which is one step in the manufacturing method shown in FIG. 7.

FIG. 11 is a graph showing another example of a temperature profile.

FIG. 12 is a view showing an ACF sticking step which is one step in the manufacturing method shown in FIG. 7.

FIG. 13 is a perspective view showing in an exploded state a liquid crystal device which is one embodiment of a display device according to the present invention.

FIG. 14 is a plan view showing an electroluminescence device which is another embodiment of a display device according to the present invention.

FIG. 15 is a sectional view showing the sectional structure of the electroluminescence device taken along line I-I in FIG. 14.

FIG. 16 is a sectional view showing the sectional structure of the electroluminescence device taken along line II-II in FIG. 14.

FIG. 17 is a side sectional view showing a tentative compression bonding step which is one step in the manufacturing method shown in FIG. 7.

### PREFERRED EMBODIMENTS

Now, preferred embodiments of the present invention will be described more specifically with reference to the drawings.

(Embodiment of Circuit Board)

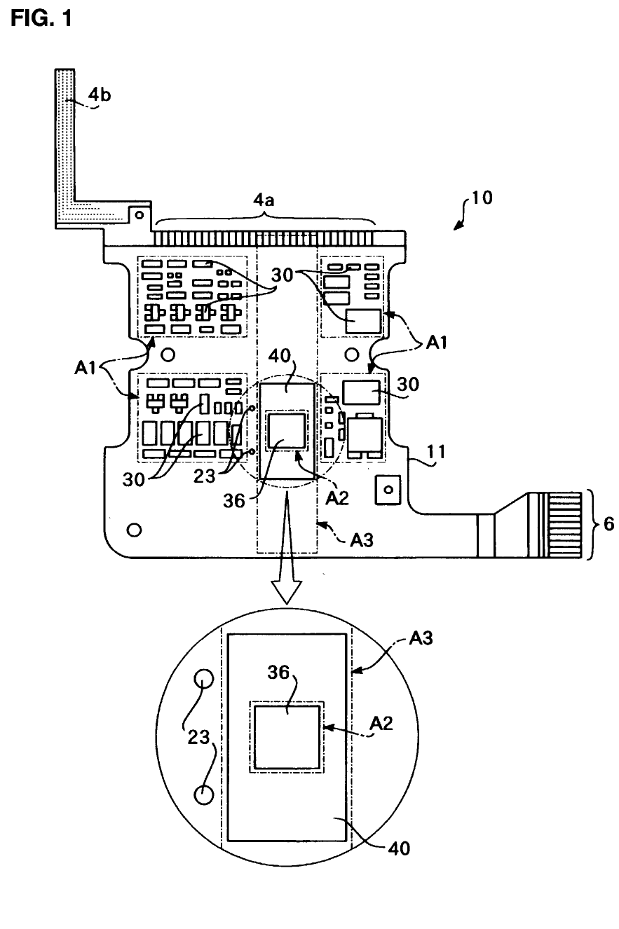

FIG. 1 is a plan view showing construction of one embodiment of a circuit board according to the present invention. The circuit board 10 shown here has a substrate 11 which determines the external shape of the circuit board 10, first components 30 which are solder-connected to the substrate 11, and a second component 36 which is mounted on the substrate 11 with an ACF (Anisotropic Conductive Film) 40 interposed therebetween. Used as the first components 30 are, for example, passive elements such as a chip resistor and a chip capacitor, and a mechanism component such as variable resistor. -A semiconductor device such as IC or LSI, for example, is used as the second component 36. The first components 30 are secured within first regions A1. -The second component 36 is secured within a second region A2.

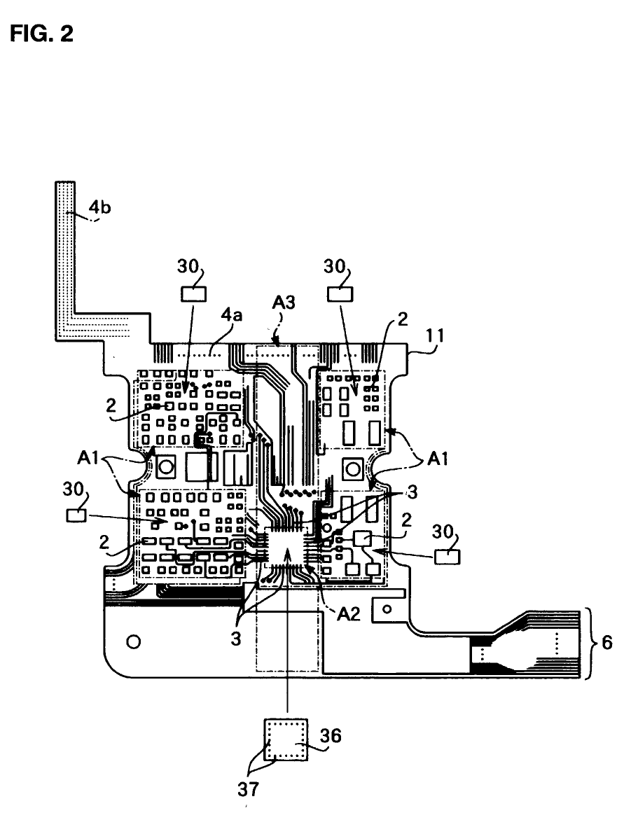

FIG. 2 shows in plan the substrate 11 before the first components 30 and the second component 36 are mounted thereon. As shown in FIG. 2, a plurality of lands 2 for mounting the first components 30 are formed in predetermined patterns within each of the first regions A1 of the front surface of the substrate 11. A plurality of leads 3 for mounting the second component 36 are laid within the second region A2. The marginal end parts of the substrate 11 are formed with various terminals such as output side first terminals 4a which are formed toward the front surface side of the drawing, output side second terminals 4b which are formed toward the back surface side of the drawing, and input side terminals 6 which are formed toward the front surface side of the drawing.

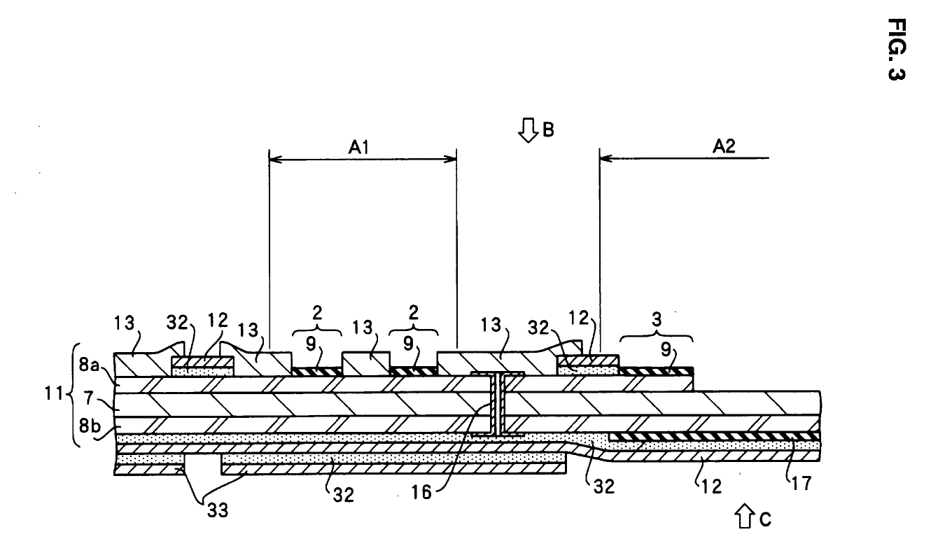

As shown in FIG. 3, the substrate 11 includes a base 7. A wiring line 8a is formed in a predetermined pattern as viewed in the direction of arrow B on the front surface side of the base 7 (on the upper surface side of a structure shown in FIG. 3), electrodes 9 are formed on the suitable parts of the wiring line 8a, and the lands 2 and the leads 3 are formed by the electrodes 9.

Layers such as coverlet layers 12 and resist layers 13 are formed by the use of an adhesive 32 in an extensive range except the first regions A1 in which the lands 2 are formed, and the second region A2 in which the leads 3 are formed. The coverlet layers 12 serve, for example, to apply elasticity to the substrate 11 so that the substrate 11 may lie at the neutral point of bending. The resist layers 13 serve, for example, to protect the wiring line 8a, etc. from damages.

A wiring line 8b is formed on the back surface side of the base 7 (on the lower surface side of the structure shown in FIG. 3), a coverlet layer 12 is stacked on the wiring line 8b through the adhesive 32, and reinforcement plates 33 are further stacked on the coverlet layer 12 through the adhesive 32. Electrical conduction is established between the wiring line 8a on the front surface side and the wiring line 8b on the back surface side by a through hole 16. Incidentally, a dummy electrode 17 is provided between the wiring line 8b and the adhesive 32 at a part which corresponds to the second region A2 where the second component 36 such as IC chip is mounted.

The dummy electrode 17 is an element which is formed of the same material as that of the electrodes 9, but which is not employed as an actual electrode. In a case where the dummy electrode 17 is viewed in plan in the direction of the arrow B, the size of the dummy electrode 17 in plan is set equal to or larger than the size of the second component 36. Accordingly, such an a real relation is held that, when the second component 36 is mounted within the second region A2, it is entirely included within the dummy electrode 17.

After the second component 36 has been mounted within the second region A2, the mounted part is viewed from the back side of the substrate 11 as indicated by arrow C. Then, the mounted state of the second component 36 can be visually confirmed by the deformed state of the dummy electrode 17. By way of example, in a case where the second component 36 includes a plurality of bumps annularly arrayed and where a surface formed with the bumps is a mounting surface, the dummy electrode 17 is deformed rectangularly along the annular bumps on condition that the mounting of the second component 36 is normal. Therefore, when the dummy electrode 17 rectangularly deformed has been visually confirmed, the mounting of the second component 36 can be decided normal.

Incidentally, the dummy electrode 17 may be held at a potential different from a ground potential or may be connected to the ground potential. With the dummy electrode 17 held connected to the ground potential, when the second component 36 mounted within the second region A2 is operated, noise can be prevented from coming into the second component 36 or from going out of the second component 36.

In the above stacked structure, the base 7 is formed of, for example, polyimide. The wiring lines 8a and 8b are formed of, for example, Cu (copper). The coverlet layers 12 are formed of, for example, polyimide. Each of the electrodes 9 is formed of, for example, a stacked structure which consists of a Ni (nickel) layer stacked on the wiring line 8a, and an Au (gold) layer further stacked on the Ni layer.

Referring to FIG. 2, the first components 30 are soldered to the lands 2 within the first regions A1, and the second component 36 is mounted within the second region A2 provided with the leads 3, whereby the circuit board 10 as shown in FIG. 1 is formed. Besides, in this embodiment, a band-shaped region A3 is set in addition to the first and second regions.

The band-shaped region A3 is formed as a region which includes the second region A2 and which extends in the shape of a band in the vertical direction of FIG. 2. Besides, the band-shaped region A3 is a region where any first component 30 is not mounted. Incidentally, the wiring lines 8a and 8b are formed within the belt-shaped region A3, whereby the area of the front surface of the substrate 11 is effectively utilized.

Incidentally, although one example of the second region A2 is shown in FIGS. 1 and 2, the second region A2 can be formed at any position within the band-shaped region A3, and a plurality of such second regions can also be formed within the band-shaped region A3. Besides, a plurality of such belt-shaped regions A3 may be formed.

Although the belt-shaped region A3 is formed between one pair of first regions A1, A1 adjacent to each other, that is, between one first component 30 and another first component 30 in FIG. 1, the band-shaped region A3 need not always be so set, but it may be formed at one end part of the circuit board 10.

Referring to FIG. 1, the first components 30 such as the chip resistor, chip capacitor and variable resistor are mounted within the first regions A1 by solder connection. The second component 36 such as the IC or LSI is mounted within the second region A2 by employing the ACF 40.

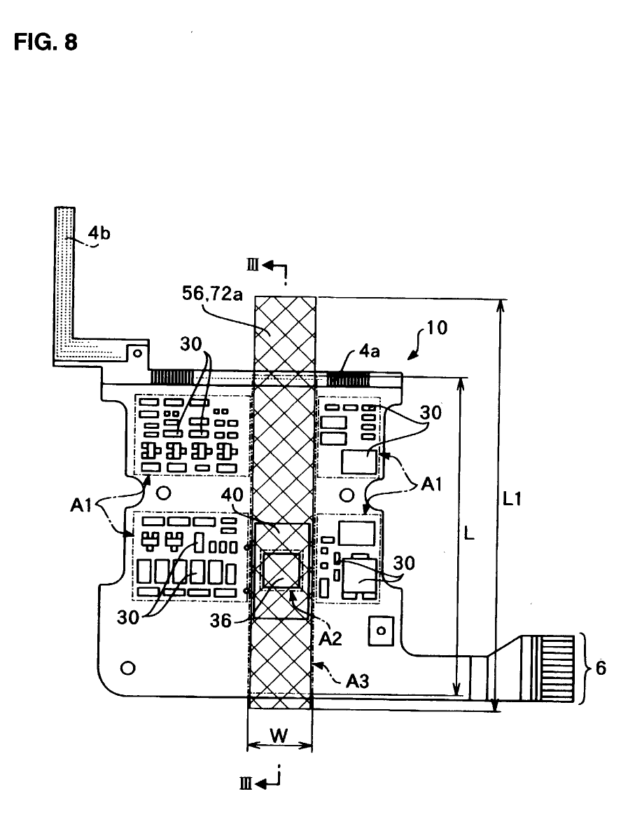

Although a manufacturing method for fabricating the circuit board 10 will be stated later, FIG. 8 shows as a plan view the positional relationship between the circuit board 10 and a region where the end face or pressing face of the head 72a of a thermocompression bonding jig for use in the manufacturing method, especially for use in mounting the second component 36 lies (a hatched region).

As apparent from FIG. 8, the band-shaped region A3 where any first component 30 is not mounted is a region which has a width W larger than that of the end face of the head 72a of the thermocompression bonding jig for use in mounting the second component 36, and a length L equal to that of a region where the end face of the head 72a and the circuit board 10 oppose.

Accordingly, even in a case where the thermocompression bonding jig is employed in order to mount the second component 36 after the mounting of the first components 30, its head 72a can be used without interfering or colliding with any of the first components 30, so that thermocompression bonding can be appropriately carried out. Therefore, the second component 36 can be reliably mounted using the head 72a. By the way, in a case where the length L1 of the end face of the head 72a is smaller than that of the, circuit board 10, the band-shaped region A3 may be a region which has a length equal to or larger than that of the region where the end face of the head 72a and the circuit board 10 oppose to each other.

Referring to FIG. 1, the circuit board 10 is provided with alignment marks 23 outside the side edge part of the band-shaped region A3. In mounting, for example, the LSI chip or IC chip as the second component 36, the alignment marks 23 are employed so as to establish a predetermined positional relationship with alignment marks provided on the LSI chip or the like, that is, in order to position the LSI chip or the like.

Since the alignment marks 23 are provided outside the side edge part of the belt-shaped region A3, it is avoidable that the alignment marks 23 be covered with the ACF 40 which is arranged on the second region A2 in mounting the second component 36 such as LSI chip. Moreover, since the alignment marks 23 are formed outside a region opposing to a pressing head 56 (refer to FIG. 8), they do not become difficult of recognition on account of dirt ascribable to their contact with the head 56, and so forth.

Incidentally, two of the alignment marks 23 are sufficient because positioning on a plane is possible, but a larger number of such alignment marks may be provided. In this case, it is possible to select alignment marks that are easy of recognition, in accordance with a manufacturing equipment. Besides, a place where the alignment marks are arranged should preferably be nearer to a positioning place. The reason therefor is that, as the alignment marks are spaced more from the positioning place, errors ascribable to the deformation of the substrate 11 become larger.

As thus far described, with the circuit board 10 of this embodiment, any of the first components 30 is not mounted on the band-shaped region A3 which extends in the shape of the band so as to include the second region A2, so that the second component 36 can be mounted with the ACF 40 by employing the thermocompression bonding head 72a (refer to FIG. 8) after the first components 30 have been mounted by soldering. It is accordingly avoidable that heat produced when using, for example, surface mount technology be applied to the ACF 40. As a result, the circuit board 10 can mount the first components 30 by the surface mount technology without lowering the reliability of connection due to the ACF 40.

(Embodiment of Manufacturing Method of Circuit Board)

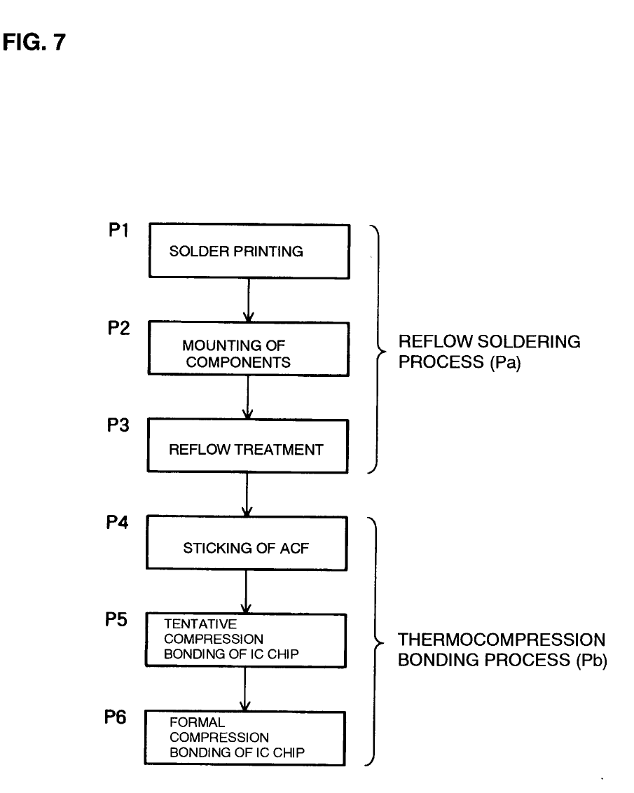

FIG. 7 shows one embodiment of the manufacturing method of a circuit board according to the present invention. In this manufacturing method, a reflow soldering process Pa is initially performed, and a thermocompression bonding process Pb is subsequently performed.

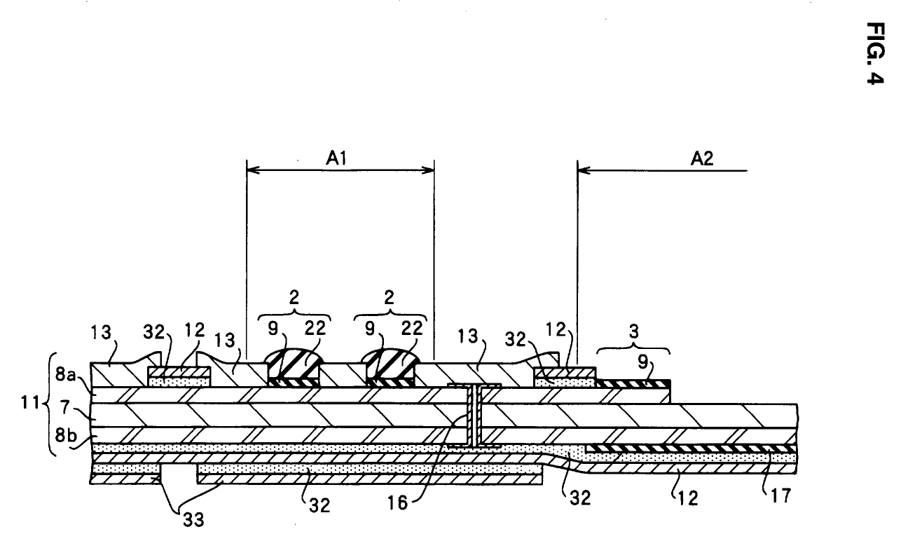

At the reflow soldering process Pa, a metal mask (not shown) having a predetermined hole pattern is first put on the front surface of a substrate 11 in FIG. 2, and a pasty solder is put on the metal mask and is spread by employing a squeegee, whereby the solder in a desired pattern corresponding to the mask pattern which the metal mask has is printed on the front surface of the substrate 11 (step P1). Thus, as shown in FIG. 4, the solder 22 is put on the lands 2 of each first region A1 of the substrate 11.

By the way, in this embodiment, a so-called “lead-free solder” which does not contain Pb (lead) shall be used as the pasty solder. In general, an ordinary solder containing Pb contains Sn (tin) as its principal ingredient and about 40% of Pb. In contrast, the lead-free solder contains Sn as its principal ingredient and has a Pb content of at most 10%. The use of the solder of low Pb content in this manner is chiefly intended for environmental protection, but this solder is higher in the melting point as compared with the ordinary solder.

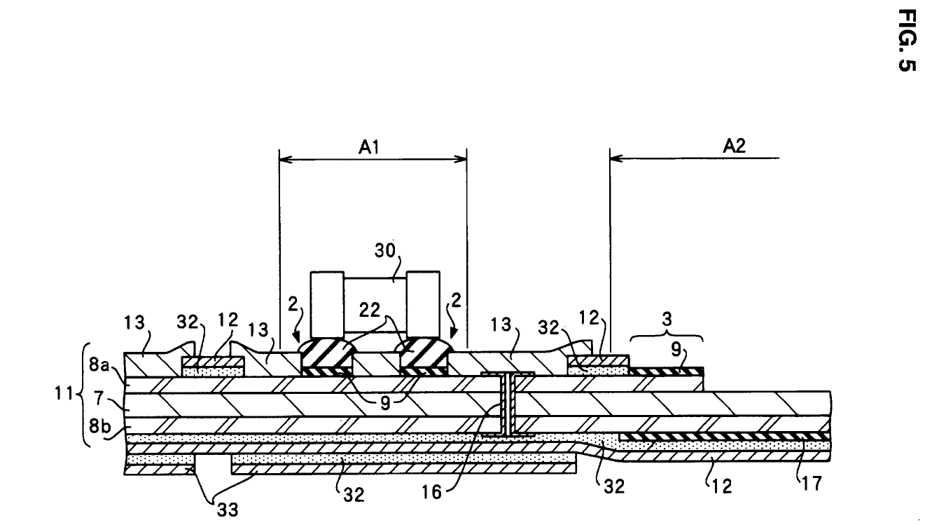

Subsequently, at a step P2, the mount treatment of each first component 30 such as a chip resistor, chip capacitor or variable resistor is performed, and the first component 30 is put on the lands 2 of the first region A1 as shown in FIG. 5. Subsequently, at a reflow treatment P3, the substrate 11 on which the first component 30 is put is conveyed into a reflow furnace (not shown), and hot air is supplied to the surface of the substrate 11 on the side thereof on which the first component 30 is put, inside the reflow furnace. Thus, the solder 22 is melted, and the plurality of first components 30 are collectively soldered to the plurality of lands 2.

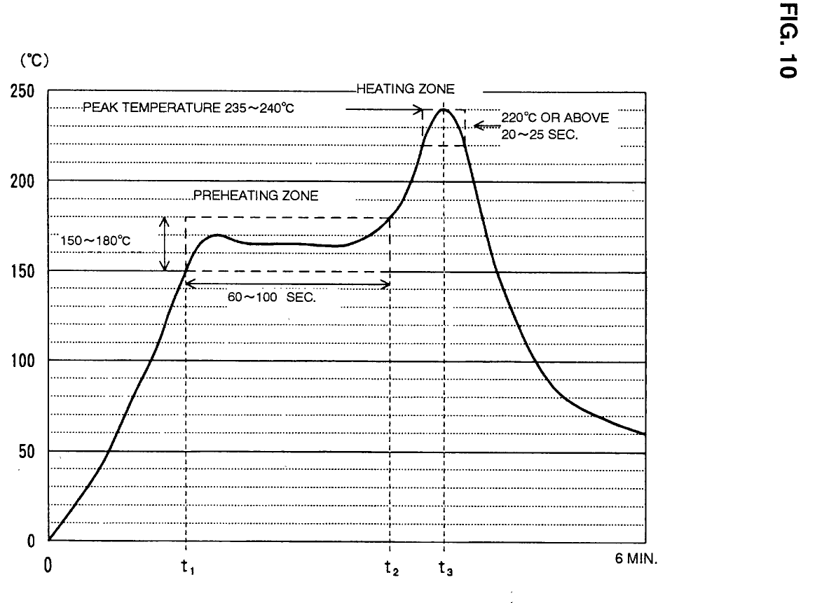

Heating for the substrate 11 inside the reflow furnace for use in this embodiment is carried out in accordance with, for example, a temperature profile as shown in FIG. 10. Referring to FIG. 10, the axis of abscissas indicates the time variation of one point of the substrate 11 that is being moved in the reflow furnace, while the axis of ordinates indicates the variation state of the temperature of the point.

As shown in FIG. 10, the substrate 11 conveyed into the reflow furnace and being moved in the furnace has its temperature raised up to 150-180° C. in a time period t1, it is thereafter preheated at a constant temperature of 150-180° C. for a time period of 60-100 seconds, and it is thereafter heated so as to reach a peak temperature of 235-240° C. at a time t3. Owing to the heating, the solder 22 is melted to secure the first component 30 to the lands 2 in FIG. 5. In the vicinity of the peak temperature at the time t3, the substrate 11 is held at or above 220° C. for 20-25 seconds. A time period for which the substrate 11 is held in the reflow furnace is about 6 minutes.

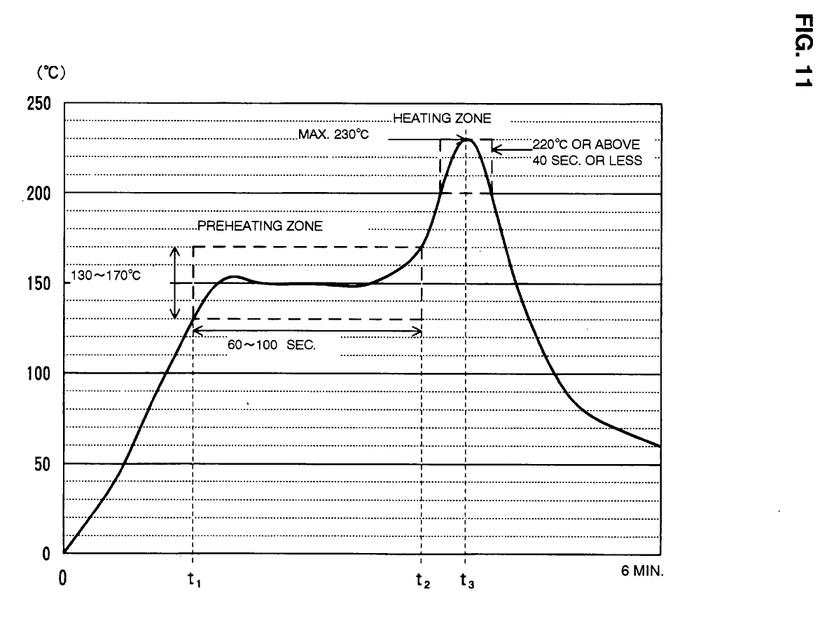

By the way, in a case where the ordinary solder containing Pb is employed as the solder, a temperature profile as shown in FIG. 11, for example, is adopted in the reflow furnace. The profile of a temperature flow in FIG. 11 is generally lower in temperature as compared with the profile in the case of the lead-free solder shown in FIG. 10. Specifically, the substrate has its temperature raised up to 130-170° C. in a time period t1, it is thereafter preheated at 130-170° C. for 60-100 seconds, and it is thereafter heated so as to reach a peak temperature of about 230° C. at a time t3. In the vicinity of the peak temperature at the time t3, the substrate 11 is held at or above 200° C. for 40 seconds or less.

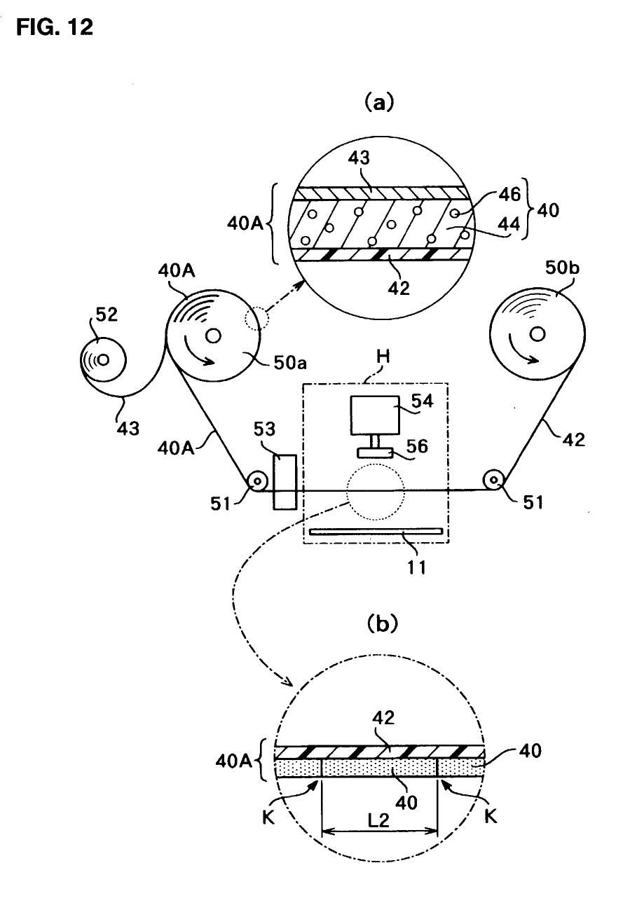

When, owing to the above, the reflow soldering process Pa has ended to end the soldering of the first components 30, operations proceed to the thermocompression bonding process Pb. In this thermocompression bonding process Pb, the step of sticking an ACF is first performed as a step P4 in a way shown in FIG. 12 by way of example. Referring to FIG. 12, an elongate ACF material 40A wound round a delivery reel 50a is taken up round a takeup reel 50b through tension rollers 51.

As shown in FIG. 12(a), the ACF material 40A wound round the delivery reel 50a is so formed that the elongate ACF 40 is stacked on release paper 42, and that a cover film 43 is further stacked on the ACF 40. The release paper 42 is formed of, for example, white PET (polyethylene terephthalate) to a thickness of about 53 μm. The cover film 43 is formed of, for example, transparent PET to a thickness of about 25 μm.

The ACF 40 is formed, for example, in such a way that a large number of conductive particles 46 are mixed in a dispersed state into a binder resin 44 which is formed of an epoxy type resin being a thermosetting resin. The thickness of the ACF 44 is set at about 35 μm.

The ACF material 40A delivered from the delivery reel 50a has its cover film 43 removed when passing through a doffer[peeling?] roller 52, and is subsequently fed to a cutting device 53. As shown in FIG. 12(b), the cutting device 53 provides cuts K in the elongate ACF 40 so as to form the ACF 40 of predetermined length L2. On this occasion, no cut is provided in the release paper 42.

The ACF material 40A which has the ACF 40 provided with the cuts K is subsequently carried to a sticking stage H on which a substrate 11 is located. A pressing device 54 which includes a pressing head 56 is disposed in the sticking stage H. The pressing head 56 is heated to a high temperature by a heater.

When one piece of ACF 40 included in the ACF material 40A is set to a predetermined position relative to the substrate 11, the pressing head 56 moves downwards in FIG. 12 and presses the ACF material 40A against the substrate 11 from the side of the release paper 42. Thus, the ACF 40 is pressed against the substrate 11 at a temperature of about 70° C. for a time period of about one second. Thereafter, when the pressing head 56 is moved back to a retreat position spaced from the substrate 11, the release paper 42 comes away from the substrate 11, and only the ACF 40 is left on the substrate 11. In this way, as shown in FIG. 1, the ACF 40 is stuck so as to cover a second region A2 at the predetermined position.

Thereafter, the alignment and tentative compression bonding treatment of a second component 36 such as IC chip are performed at a step P5 in FIG. 7. Specifically, referring to FIG. 2, the second component 36 is put on the second region A2 with the ACF 40 interposed therebetween so that terminals or bumps 37 annularly arrayed on the second component 36 may correspond respectively to individual leads 3 within the second region A2, followed by the tentative compression bonding. On this occasion, alignment marks 23 in FIG. 1 are employed in order to bring the relative positions of the second component 36 and substrate 11 into exact agreement.

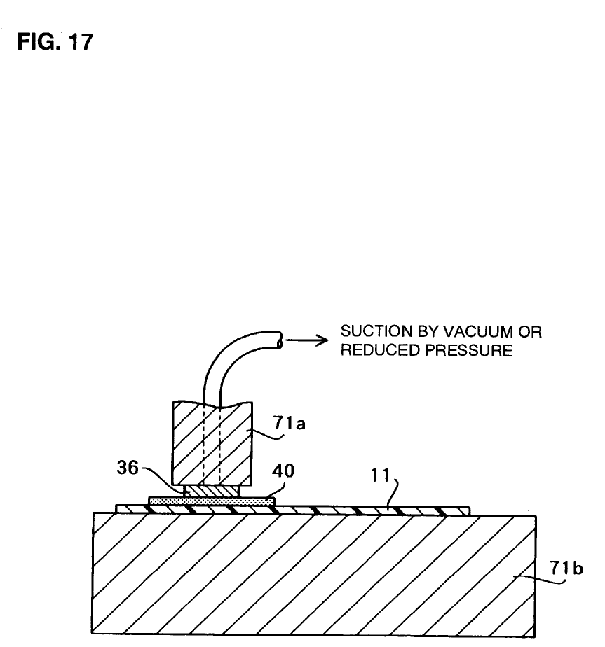

The tentative compression bonding of the second component 36 proceeds specifically in such a way that the substrate 11 is put on a table 71b as shown in FIG. 17, and that the second component 36 is pressed by a conveyance and thermocompression bonding head 71a for the heated second component 36, as shown in FIGS. 8 and 17. Thus, the second component 36 is pressed against the substrate 11 with the ACF 40 interposed therebetween at about 70° C. for about one second. Owing to the heating and pressing, the second component 36 is tentatively secured onto the substrate 11.

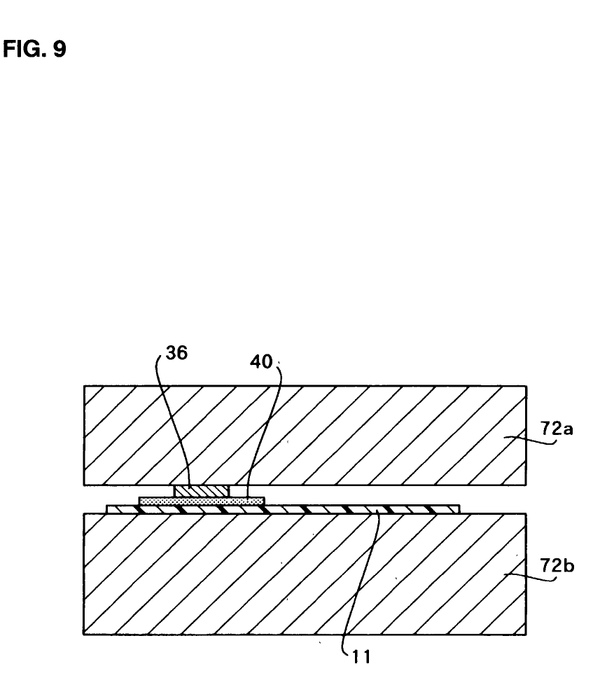

Subsequently, the operating flow proceeds to a step P6, at which the formal compression bonding of the second component 36 is performed. Specifically, the substrate 11 is put on a table 72b as shown in FIG. 9, and the second component 36 is pressed by a heated thermocompression bonding head 72a as shown in FIGS. 8 and 9. Thus, the second component 36 is pressed against the substrate 11 with the ACF 40 interposed therebetween at about 190° C. for about 10 seconds.

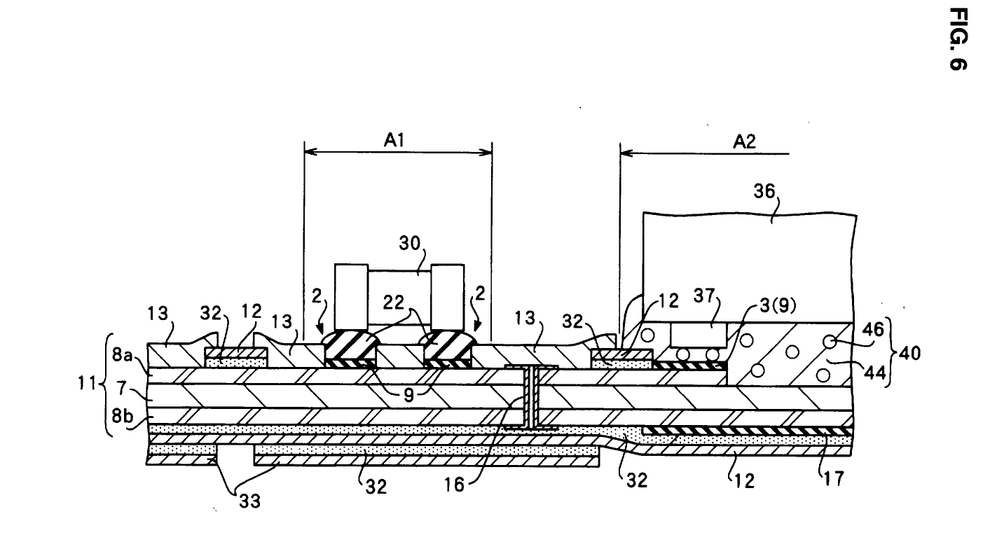

Owing to the heating and pressing, the second component 36 is formally compression-bonded onto the substrate 11, that is, it is secured with the final securing strength. As a result, the second component 36 is mounted within the second region A2 as shown in FIG. 6. More specifically, the second component 36 is secured to the substrate 11 by the resin 44 contained in the ACF 40, and the bumps 37 of the second component 36 and the leads 3 on the substrate 11 are conductively connected by the conductive particles 46 in the ACF 40.

In the formal compression bonding, the second component 36 is pressed against the substrate 11 at the higher temperature for the longer time period than in the tentative compression bonding. The reason why the formal compression bonding is preceded by the tentative compression bonding, is that the positioning or alignment between the second component 36 and the substrate 11 is difficult to be effected in the formal compression bonding.

In the above manufacturing method, as also shown in FIG. 8, the thermocompression bonding head 56 or 72a is so shaped as to extend over a region which is much longer than the length of the second component 36 or ACF 40. However, the thermocompression bonding head 56 or 72a does not come into touch with any of the first components 30 because it lies within the width W of a belt-shaped region A3 where first components 30 are not mounted.

By the way, in FIG. 9, the shape of the table 72b which lies on the opposite side to the head 72a with the substrate 11 interposed therebetween need not always the same as that of the head 72a. However, it is required at least that the area of the end face or substrate receiving surface of the table 72b be equal to or larger than the area of the surface of the second component 36 to be compression-bonded with the substrate 11. It is also required as the positional relation between the second component 36 and the table 72b that the surface of the second component 36 to be compression-bonded with the substrate 11 entirely overlap the end face of the table 72b in plan.

As thus far described, with the manufacturing method of this embodiment, first of all, the first components 30 such as passive components and mechanism components are mounted on the substrate 11 by the reflow treatment, namely, the solder connection employing surface mount technology. Subsequently, the ACF 40 is arranged at the predetermined position on the substrate 11, the second component 36 such as IC chip is put on the ACF, and the second component 36 is thermocompression-bonded. As a result, it is avoidable that heat at, for example, the solder connection step based on the surface mount technology be applied to the ACF 40. Therefore, the first components 30 can be mounted by the surface mount technology or the like without lowering the reliability of the connection of the second component 36 due to the ACF 40.

(Embodiment of Display Device)

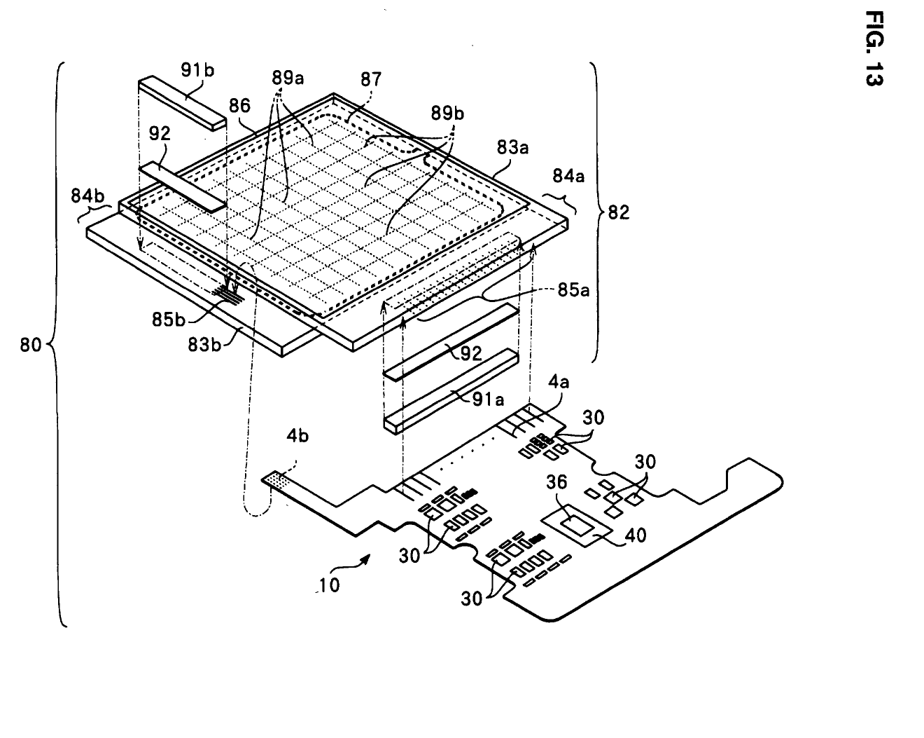

FIG. 13 shows one embodiment of a display device according to the present invention. This embodiment is an embodiment in the case where the present invention is applied to a liquid crystal device of simple matrix scheme and COG (Chip On Glass) scheme. In case of this embodiment, a circuit board 10 shown in FIG. 1 can be formed so as to include driver circuits for driving a liquid crystal panel which constitutes the liquid crystal device as the display device.

Referring to FIG. 13, the liquid crystal device 80 as the display device is formed by connecting the circuit board 10 to the liquid crystal panel 82. If necessary, the liquid crystal panel 82 can be additionally provided with an illumination device such as back light (not shown) and other accessory structures (not shown).

The liquid crystal panel 82 includes a pair of substrates 83a and 83b whose peripheral edges are bonded to each other by an annular sealant 87, and an interspace defined between the substrates 83a and 83b, namely, a so-called “cell gap” is filled up with a liquid crystal of, for example, STN (Super Twisted Nematic) type. In general, the substrates 83a and 83b are formed of a light-transmissive material, for example, glass or synthetic resin.

Polarizer plates 86 are respectively attached to the outside surfaces of the substrates 83a and 83b by adhesion or the like. A phase difference plate (not shown) is inserted between at least either of the substrates 83a and 83b and the polarizer plate 86. Striped electrodes 89a are formed on the inside surface of one substrate 83a. Striped electrodes 89b are formed on the inside surface of the other substrate 83b so as to intersect orthogonally to the opposing electrodes 89a. These electrodes 83a and 83b are formed of a light-transmissive conductive material, for example, ITO (Indium Tin Oxide).

Incidentally, the electrodes 83a and 83b are not restricted to the shape of stripes, but they can also be formed as characters, numerals or any other appropriate patterns. In FIG. 13 the electrodes 89a and 89b are depicted in a smaller number and at wider mutual intervals than in actual electrodes in order to facilitate understanding their structures, but in practice a larger number of electrodes are formed at narrower intervals.

One substrate 83a includes a protrusion 84a which protrudes outside the other substrate 83b, while the other substrate 83b includes a protrusion 84b which protrudes outside one substrate 83a. Liquid crystal driving ICs 91a and 91b are respectively mounted on these protrusions by employing ACFs 92. External connection terminals 85a which are to be connected to the inputting bumps of the liquid crystal driving IC 91a are formed on one protrusion 84a by the use of, for example, ITO simultaneously with the formation of the electrodes 89a. Also, external connection terminals 85b which are to be connected to the inputting bumps of the liquid crystal driving IC 91b are formed on the other protrusion 84b by the use of, for example, ITO simultaneously with the formation of the electrodes 89b.

The connection between the circuit board 10 and the liquid crystal panel 82 is made, for example, in such a way that the external connection terminals 85a formed on the protrusion 84a of the substrate 83a of the liquid crystal panel 82 and output side first terminals 4a formed at the marginal end part of the circuit board 10 are conductively connected by an ACF, and that the external connection terminals 85b formed on the protrusion 84b of the substrate 83b and output side second terminals 4b formed at the marginal end part of the narrow portion of the circuit board 10 are conductively connected by an ACF.

The ACFs are formed of a binding resin and conductive particles that are mixed in the resin, as in the ACF which is used for connecting a second component 36 to a substrate 11 in a circuit board 10 shown in FIG. 1. When thermal compression bonding is performed, the circuit board 10 and the substrates 83a and 83b in FIG. 13 are secured by the binding resin, and the terminals 4a, 4b of the circuit board 10 and the corresponding connection terminals 85a, 85b of the liquid crystal panel 82 are conductively connected by the conductive particles.

Incidentally, the embodiment shown in FIG. 13 adopts the structure in which the liquid crystal driving ICs 91a and 91b are directly mounted on the corresponding substrates 83a and 83b of the liquid crystal panel 82, namely, the structure of the so-called “COG (Chip On Glass) scheme”, so that any liquid crystal driving IC need not be mounted on the circuit board 10. Accordingly, a semiconductor device different from the liquid crystal driving IC, for example, a power source IC or a power source LSI is considered as the second component 36 which is mounted on the circuit board 10 in this case.

(Another Embodiment of Display Device)

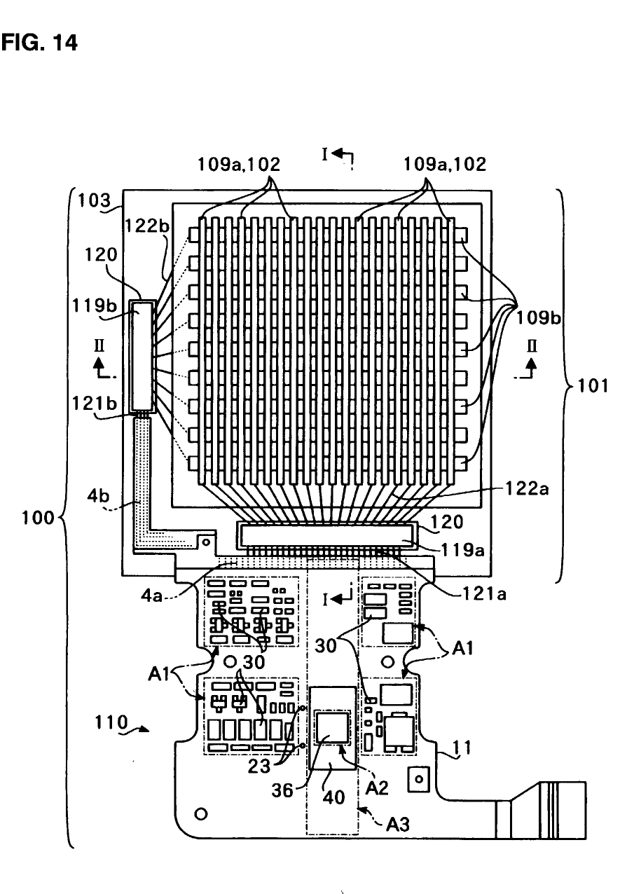

FIG. 14 shows another embodiment of a display device according to the present invention. This embodiment is an embodiment in the case where the present invention is applied to an electroluminescent device as the display device. The electroluminescent device 100 shown here is constructed by connecting a circuit board 110 to an EL panel 101.

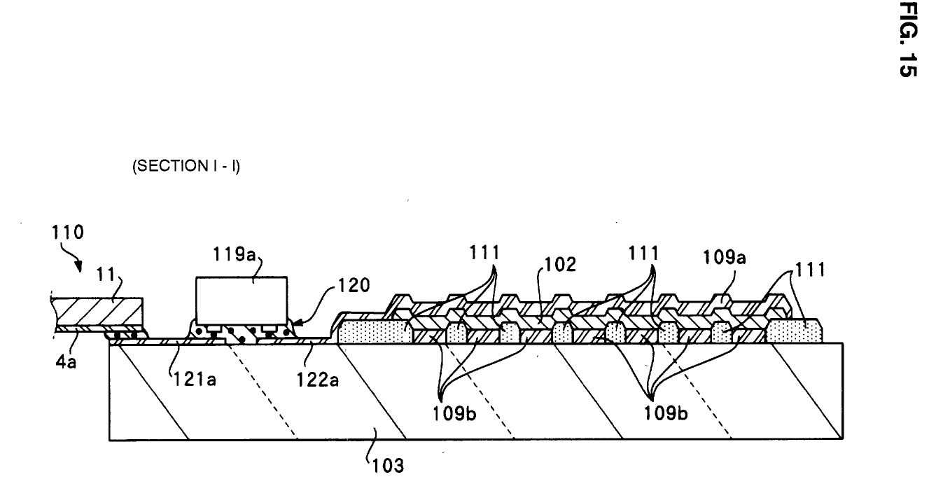

As shown in FIG. 15 which is a sectional view taken along line I-I, the EL panel 101 is fabricated in such a way that a plurality of positive electrodes or anodes 109b are formed on a baseplate 103 in parallel with one another at intervals, that insulator films 111 are formed between the anodes 109b and overlaid with organic electroluminescent emission layers 102, and that negative electrodes or cathodes 109a are formed on the electroluminescent emission layers.

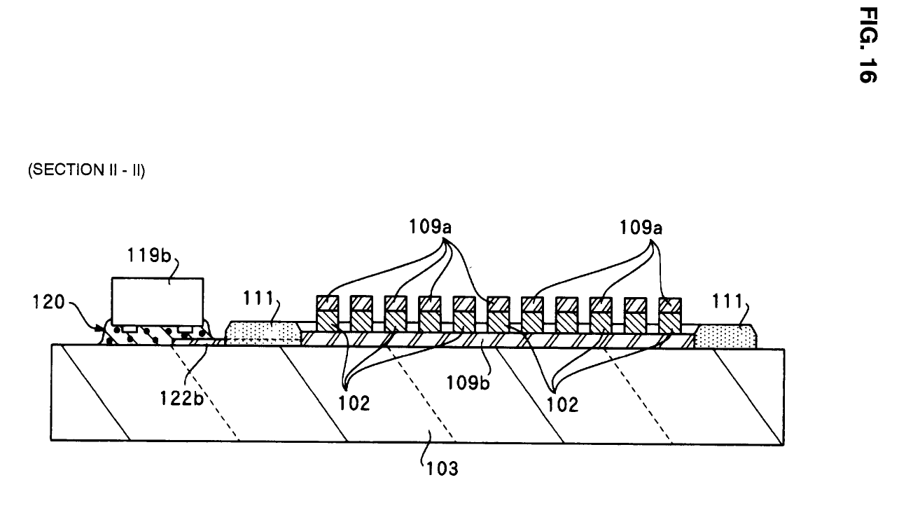

As shown in FIG. 14, the plurality of anodes 109b are arrayed in parallel with one another at intervals and are generally formed in the shape of stripes. The plurality of cathodes 109a are arrayed similarly in parallel with one another at intervals, and so as to intersect substantially orthogonally to the anodes 109b, and they are generally formed in the shape of stripes. As also seen from FIG. 16 which is a sectional view taken along line II-II in FIG. 14, the organic electroluminescent emission layers 102 are respectively-formed at substantially the same positions as those of the cathodes 109a.

As is well known, each of the organic electroluminescent emission layers 102 is made of a substance which luminesces in an inherent color when a predetermined voltage is applied across electrodes holding the layer therebetween. In this embodiment, by way of example, three sorts of emission layers which luminesce in red, in green and in blue, respectively, are arranged in adjacency to one another into one unit, and such units are arrayed in parallel with one another in the extending direction of the anodes 109b, that is, in the lengthwise direction of the anodes 109b.

Each region where the anode 109b and the cathode 109a intersect each other while holding the individual organic electroluminescent emission layers 102 in the three colors of red, green and blue therebetween forms one display dot, and three such display dots gather to form one pixel. Such pixels are arrayed in the shape of a matrix within a plane, whereby a display region for displaying an image such as characters, numerals and patterns is formed.

Referring to FIG. 14, a driving IC 119a is mounted on the marginal end part of the lower side of the baseplate 103 by an ACF 120, while a driving IC 119b is mounted on the marginal end part of the left side by an ACF 120. The inputting bumps of the driving IC 119a are joined to external connection terminals 121a formed at the marginal end part of the baseplate 103, and the outputting bumps of the driving IC 119a are joined to the cathodes 109a through wiring lines 122a formed on the baseplate 103. On the other hand, the inputting bumps of the driving IC 119b are joined to external connection terminals 121b formed on the baseplate 103, and the outputting bumps of the driving IC 119b are joined to the anodes 109b through wiring lines 122b formed on the baseplate 103.

As in the circuit board 10 shown in FIG. 1, the circuit board 110 includes output side first terminals 4a and output side second terminals 4b. In the case of the circuit board 10 in FIG. 1, however, the first terminals 4a are formed on the front side of the circuit board 10, and the second terminals 4b are formed on the back side of the circuit board 10, whereas in the case of the circuit board 110 in FIG. 14, both the first terminals 4a and the second terminals 4b are formed on the back side of the circuit board 110.

It is the same as in the circuit board 10 shown in FIG. 1 that the circuit board 110 has first components 30 within first regions A1, a second component 36 within a second region A2, and a band-shaped region A3 including the second region A2. The second component 36 is constructed of, for example, a power source IC or a power source LSI.

Since the electroluminescent device 100 according to this embodiment is constructed as described above, desired coordinate positions are caused to exhibit luminescence in desired colors by controlling voltages to be applied to the organic electroluminescent emission layers 102 at the respective display dots. Owing to the luminescing, the images such as characters, numerals and patterns are displayed in desired colors within the display region in accordance with the principle of the additive mixture of color stimuli.

(Modifications)

Although in the embodiments described above, only one example has been indicated as each of the shape of the circuit board and the component arrangement on the circuit board, the shape of the circuit board, etc. can be variously altered and changed within the scope of the invention as defined in the appended claims.

Furtheremore, in the embodiments described above, examples of the display devices employing the liquid crystal panel and the EL panel have been indicated as display means, but the display means is not restricted to the liquid crystal panel or the EL panel, and it may be any of a CRT display, a plasma display, an FED (Field Emission Display), etc.

Besides, the present invention is not restricted to the foregoing embodiments, but various modified embodiments are possible within the scope of the purport of the present invention or within the equivalent scope of the appended claims.

What is claimed is:

1. A circuit board, the circuit board characterized by comprising:
a substrate;
a first component which is mounted on said substrate by solder connection;
a second component which is mounted on said substrate with an anisotropic conductive film interposed therebetween; and
a band-shaped region which extends in the shape of a band while including said second component, and which does not include said first component.

2. A circuit board according to claim 1, characterized in that said first component is a passive element or a mechanism component, while said second component is a semiconductor device.

3. A circuit board according to claim 1, characterized in that said band-shaped region is wider than a pressing surface of a thermocompression bonding head which is employed in mounting said second component.

4. A circuit board according to claim 1, characterized in that an alignment mark is provided outside said belt-shaped region.

5. A circuit board according to claim 1, characterized in that the solder connection includes a reflow treatment.

6. A circuit board according to claim 1, characterized in that a plurality of said first components are disposed, and that said band-shaped region is located between the plurality of first components.

7. A circuit board according to claim 6, characterized in that said second component is a power source IC or a power source LSI.

8. A circuit board according to claim 1, characterized in that said band-shaped region is disposed extending from one end to another end of said substrate.

9. A circuit board according to claim 1, characterized in that said band-shaped region extends rectilinearly.

10. A circuit board according to claim 1, characterized in that wiring patterns are formed in said band-shaped region.

11. A circuit board according to claim 1, characterized in that a dummy electrode is formed at a position on said substrate corresponding to said second component.

12. A display device characterized by comprising said circuit board of the construction defined in claim 1, and display means to which said circuit board is connected.

13. A display device according to claim 12, characterized in that said display means is constructed of a liquid crystal device which includes substrates, and that said circuit board is connected to said substrates.

14. A display device according to claim 12, characterized in that a plurality of said first components are disposed, that said band-shaped region is located between the plurality of first components, and that said second component is a power source IC, a power source LSI, a liquid crystal driving IC or a liquid crystal driving LSI.

15. A method of manufacturing a circuit board characterized by comprising:
the step of mounting a first component on a substrate by solder connection;
the step of arranging an anisotropic conductive film on a predetermined position of the substrate;
the step of arranging a second component on the anisotropic conductive film; and
the step of thermocompression-bonding the second component to said substrate with said anisotropic conductive film held therebetween;
wherein said step of arranging said anisotropic conductive film on the predetermined position of said substrate is performed after said step of mounting the first component on said substrate by the solder connection.

16. A method of manufacturing a circuit board according to claim 15, characterized in that said step of mounting said first component on said substrate by the solder connection includes a reflow treatment.
